(19) United States
(12) Patent Application Publication
(10) Pub. No.: US 2024/0405051 A1
(43) Pub. Date: Dec. 5, 2024

(54) PHOTOELECTRIC CONVERSION APPARATUS, PHOTOELECTRIC CONVERSION SYSTEM, AND MOVING BODY

(71) Applicant: CANON KABUSHIKI KAISHA, Tokyo (JP)

(72) Inventors: DAIKI SHIRAHIGE, Kanagawa (JP); TAKAFUMI MIKI, Kanagawa (JP)

(21) Appl. No.: 18/673,157

(22) Filed: May 23, 2024

(30) Foreign Application Priority Data
May 29, 2023 (JP) 2023-087970

(51) Int. Cl. H01L 27/146

(52) U.S. Cl. CPC H01L 27/14636; H01L 27/14605; H01L 27/14612; H01L 27/14641; H01L 27/14643

(57) ABSTRACT

A photoelectric conversion apparatus includes a first conductive line that is arranged in a first wiring layer and connects a floating diffusion to a gate of an amplification transistor, a shielding portion that is made of metal and provided in a second wiring layer which is an upper layer of the first wiring layer such that at least one portion of the shielding portion overlaps the first conductive line in a plan view, and a second conductive line that is arranged on a third wiring layer which is an upper layer of the second wiring layer such that at least one portion of the second conductive line overlaps the first conductive line in the plan view. The shielding portion includes a plurality of insulation portions in the plan view.

### BACKGROUND

### Field

The present disclosure relates to a photoelectric conversion apparatus, a photoelectric conversion system, and a moving body.

### Description of the Related Art

Photoelectric conversion apparatuses are known that transfer an electric charge photoelectrically converted by a photodiode to a floating diffusion (FD) and amplify a signal as a voltage signal. In such a photoelectric conversion apparatus, a metal conductive line may be used as a shield to reduce an influence on the FD due to potential fluctuation from a conductive line that is not connected to the FD.

In a case where a metal conductive line is used as a shield, there is a concern that a metal conductive line portion may be recessed by scratch or dishing, for example, in a planarization process at the time of manufacture. The recess of the metal conductive line portion causes a recess to be formed on an interlayer film that is arranged in the metal conductive line portion. In a subsequent damascene process, the recess in the interlayer film is filled with metal. Consequently, a short circuit may occur among conductive lines. Such a short circuit is a factor of a decrease in yield.

### SUMMARY

According to some embodiments, a photoelectric conversion apparatus may include a photoelectric conversion unit configured to generate a signal electric charge based on incident light, a transfer transistor configured to transfer the electric charge generated by the photoelectric conversion unit to a floating diffusion, an amplification transistor including a gate to which a signal based on a potential of the floating diffusion is input, a wiring structure body including at least a first wiring layer, a second wiring layer which is an upper layer of the first wiring layer, and a third wiring layer which is an upper layer of the second wiring layer, a first conductive line arranged in the first wiring layer and configured to connect the floating diffusion to the gate, a shielding portion made of metal and arranged in the second wiring layer such that at least one portion of the shielding portion overlaps the first conductive line in a plan view, and second conductive line arranged in the third wiring layer such that at least one portion of the second conductive line overlaps the first conductive line in the plan view. The shielding portion includes a plurality of insulation portions in the plan view.

Further features of the present disclosure will become apparent from the following description of exemplary embodiments with reference to the attached drawings.

### BRIEF DESCRIPTION OF THE DRAWINGS

FIG. 1 is a schematic diagram of a photoelectric conversion apparatus according to a first exemplary embodiment.

FIG. 2 is an equivalent circuit diagram of a pixel according to the first exemplary embodiment.

FIG. 3 is a schematic diagram of the pixel according to the first exemplary embodiment.

FIG. 4 is a cross-sectional view of the pixel according to the first exemplary embodiment.

FIG. 5 is a schematic diagram of a pixel according to a related-art structure.

FIG. 6 is a schematic diagram of a pixel according to a second exemplary embodiment.

FIG. 7 is a schematic diagram of a pixel according to a third exemplary embodiment.

FIG. 8 is a schematic diagram of a pixel according to a fourth exemplary embodiment.

FIG. 9 is a schematic diagram of a pixel according to a fifth exemplary embodiment.

FIG. 10 is a schematic diagram of a photoelectric conversion system according to a sixth exemplary embodiment.

FIGS. 11A and 11B are schematic diagrams of a moving body according to a seventh exemplary embodiment.

### DESCRIPTION OF THE EMBODIMENTS

Various exemplary embodiments, features, and aspects of the present disclosure are hereinafter described with reference to the drawings. In the following description and the drawings, configurations common throughout a plurality of drawings are given the same reference codes. The common configuration is therefore described by referring to the plurality of the drawings, and description of the configuration having the same reference code may be appropriately omitted.

A metal member such as a conductive line described in the present specification can be made of one single metal as an element or a mixture (alloy). For example, a conductive line can contain only copper or can contain copper as a main component and other components. The copper conductive line herein is one example, and conductive line components can be changed to various kinds of metal.

In the exemplary embodiments described below, a connection of circuit elements may be mentioned. In such a case, even if there is an element between target elements, the target elements are treated as if they were connected to each other unless otherwise noted. For example, it is assumed that an element A is connected to one node of a capacitative element C having a plurality of nodes, and an element B is connected to the other node of the capacitative element C. Even in such a case, the elements A and B are regarded as being connected to each other unless otherwise noted.

In the present specification, the term “plan view” represents a plan as seen from a direction perpendicular to a light incident surface of a semiconductor substrate or a surface opposite to the light incident surface and corresponds to a two-dimensional plan view obtained by projecting components of the photoelectric conversion apparatus onto a surface of the semiconductor substrate.

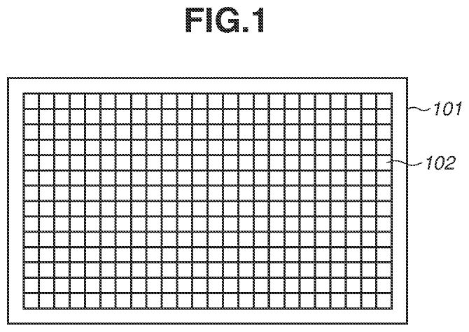

A first exemplary embodiment is described with reference to FIGS. 1 through 4. FIG. 1 is a schematic top view of a photoelectric conversion apparatus 101. The photoelectric conversion apparatus 101 includes a plurality of pixels 102 in a semiconductor substrate. Each of the pixels 102 outputs incident light as an electric signal. In FIG. 1, circuits are omitted, such as a vertical scanning circuit, a horizontal scanning circuit, a timing generator, and an analog-to-digital conversion circuit. Alternatively, the photoelectric conversion apparatus 101 may include a first substrate and a second substrate that are laminated. In such a case, the first substrate includes a plurality of pixel 102, and the second substrate different from the first substrate includes each of the circuits.

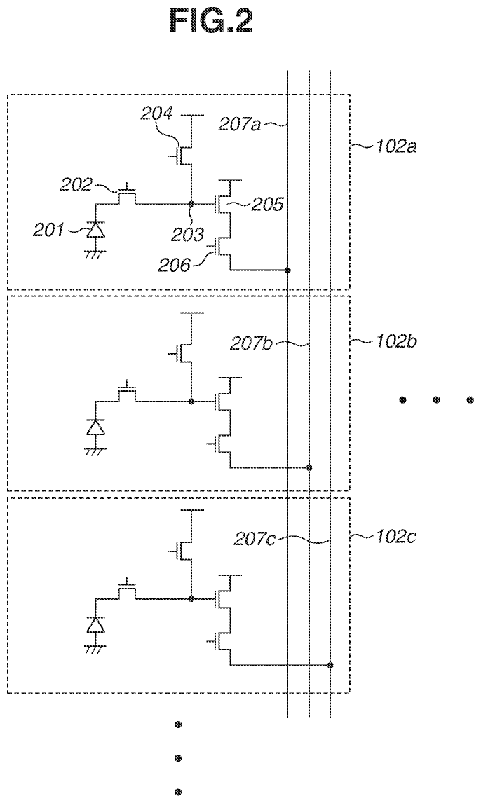

FIG. 2 is an equivalent circuit diagram of the pixels 102 (102a, 102b, and 102c). In FIG. 2, one photodiode (PD) 201 that is a photoelectric conversion unit is disposed in one pixel 102 for the sake of simplicity. However, the number of PDs 201 is not limited thereto. Moreover, the number of elements and the number of output lines included in one pixel 102 are not limited to those illustrated in FIG. 2.

The pixel 102 includes the PD 201, a floating diffusion (FD) 203, a transfer transistor 202 disposed between the PD 201 and the FD 203. The FD 203 is connected to a source of a reset transistor 204 and a gate of an amplification transistor 205.

A drain of the reset transistor 204 and a drain of the amplification transistor 205 are connected to a power source. A drain of a selection transistor 206 is connected to a source of the amplification transistor 205. Moreover, a source of the selection transistor 206 is connected to an output line 207 (207a, 207b, 207c).

The pixels 102 are arranged in an array, and the output line 207 of each pixel 102 is arranged across other pixels 102. One or more output lines 207 are connected to one pixel. FIG. 2 illustrates an example in which one output line 207 is connected to one pixel.

The PD 201 receives light incident on the pixel 102 and generates an electric charge correspondent to an amount of the received light.

The generated electric charge is transferred to the FD 203 by the transfer transistor 202. The FD 203 temporarily retains the electric charge transferred from the PD 201 and converts the electric charge into a voltage signal. The reset transistor 204 releases the electric charge retained by the FD 203 to a power source so that the voltage signal is reset.

The electric charge retained by the FD 203 changes a gate potential of the amplification transistor 205, and a source potential of the amplification transistor 205 fluctuates in response to such a change. This potential is output to the output line 207 in a sequential manner, so that an amount of the light incident on the photoelectric conversion apparatus 101 is output as an electric signal.

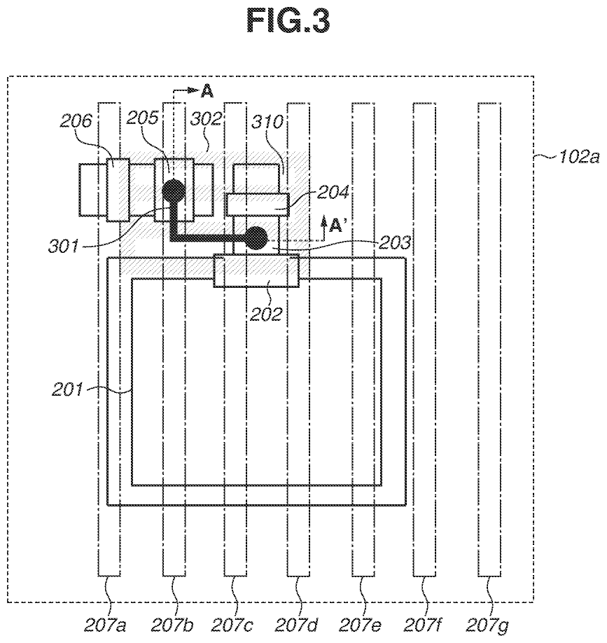

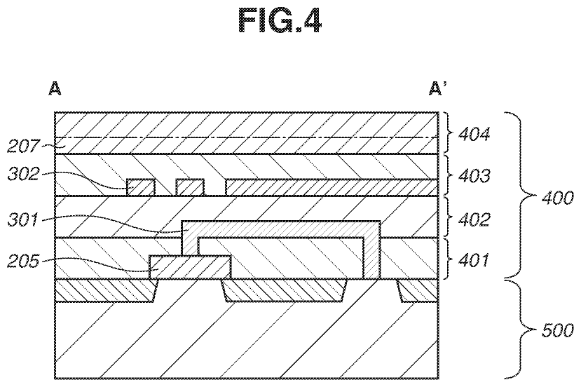

FIG. 3 is a plan view of the pixel 102 (102a) according to the present exemplary embodiment. The FD 203 is connected to a gate of the amplification transistor 205 by an FD conductive line 301. The potential fluctuation caused by the electric charge transferred to the FD 203 is thereby input to the gate of the amplification transistor 205. FIG. 4 is a cross-sectional view along the line A-A′ in FIG. 3. As illustrated in FIG. 4, the pixel 102 includes a wiring structure body 400 and a silicon layer 500. The wiring structure body 400 includes a wiring layer 401, a wiring layer 402 which is an upper layer of the wiring layer 401, a wiring layer 403 which is an upper layer of the wiring layer 402, and a wiring layer 404 which is an upper layer of the wiring layer 403.

The FD conductive line 301 is arranged in the wiring layers 401 and 402. The amplification transistor 205 and the FD conductive line 301 are connected in the wiring layer 401. The FD conductive line 301 is one component forming a capacitor of the FD 203. In a case where a potential of peripheral conductive lines capacitively coupled to the FD conductive line 301 fluctuates, a potential of the FD 203 may be affected, accordingly.

FIG. 3 illustrates an example in which seven output lines 207 (207a, 207b, 207c, 207d, 207e, 207f, and 207g) are arranged in the wiring layer 404 which is an upper layer portion of the pixel 102. In this example, the seven output lines are present on a pixel 102a. The output line 207a outputs an electric signal that is provided from the pixel 102a. The output lines 207b, 207c, 207d, 207e, 207f, and 207g output electric signals that are provided from pixels arranged in rows different from the pixel 102a.

Signals of the pixels 102 are sequentially output to the output lines 207 by the selection transistors 206. Herein, potential fluctuation of the output lines 207b, 207c, 207d, 207e, 207f, and 207g that output electric signals provided from the pixels arranged in the different rows may affect the FD conductive line 301 provided in the pixel 102a.

The shorter the distance between an output line 207 and the FD conductive line 301, the more likely the FD conductive line 301 is affected by the potential fluctuation of the output line 207 arranged in a different row. For example, the FD conductive line 301 is more affected by the output line 207 overlapping the FD conductive line 301 in the plan viegw. In the FD 203, a potential to be input to the amplification transistor 205 is changed due to the influence of the potential fluctuation. Thus, a component different from a change in potential that corresponds to an amount of light incident on the PD 201 is superimposed on an output.

Accordingly, although a conductive line such as the output line 207 is desirably not arranged in a position that overlaps the FD conductive line 301 in the plan view, layout flexibly is limited.

In addition, an FD shielding conductive line 302 is a conductive line that is provided to reduce influence of potential fluctuation on the FD conductive line 301 without limitation of layout flexibility. The FD shielding conductive line 302 is provided in the wiring layer 402 between the wiring layer 401 in which the FD conductive line 301 is arranged and the wiring layer 403 in which the output line 207 is arranged such that at least one portion of the FD shielding conductive line 302 overlaps the FD conductive line 301 in the plan view. Thus, capacitive coupling between the FD conductive line 301 and the output line 207 can be reduced, and an influence on the FD conductive line 301 due to potential fluctuation of the output line 207 can be reduced. The FD shielding conductive line 302 may be electrically connected to a source of the amplification transistor 205.

The description has been given of an influence due to potential fluctuation of the output line 207 based on positional relation between the output line 207, the FD shielding conductive line 302, and the FD conductive line 301. However, the potential fluctuation of the output line 207 may not always affect a potential of the FD conductive line 301. For example, potential fluctuation of a conductive line that drives each transistor of a pixel 102 can affect a potential of the FD conductive line 301. Accordingly, the FD shielding conductive line 302 can be arranged in a wiring layer between a wiring layer in which the FD conductive line 301 is arranged and a wiring layer in which a conductive line that drives each transistor is arranged such that at least one portion of the FD shielding conductive line 302 overlaps the FD conductive line 301 in the plan view.

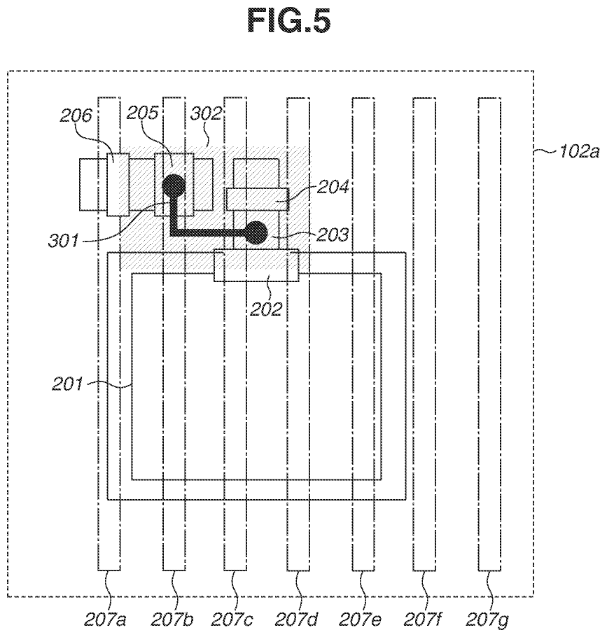

FIG. 5 is a schematic diagram of a pixel according to a related-art structure. In a case where FD shielding conductive line 302 is widely arranged as illustrated in FIG. 5, an influence of potential fluctuation from peripheral conductive lines can be reduced. However, there is a concern about a decrease in yield.

An influence on decrease in yield by the FD shielding conductive line 302 is described. When wiring is formed, a wiring layer surface may be flattened by performing chemical mechanical polishing (CMP).

At the time of flattening, an area in which metal is arranged as a material of the FD shielding conductive line 302 may be recessed more easily by scratch or dishing than an insulating film area in which a material such as silicon oxide is used. The term “scratch” herein represents a scratch mark remaining on a polished surface after polishing is finished, and the term “dishing” represents a dish-shaped dent that is formed when two kinds of thin films having a difference in polishing speed are polished. In a case where such a recess is formed, a shape of the recess may be traced onto an interlayer film that is an upper layer of the recess. Consequently, the recess of the interlayer film is also filled with metal in a subsequent damascene process. This may cause a short circuit to occur among wiring, and thus yield can be decreased.

In the present exemplary embodiment, in contrast, the FD shielding conductive line 302 has a pattern including an area (hereinafter referred to as an insulation portion 310) in which shielding wiring is not arranged so that a decrease in yield is reduced although the FD shielding conductive line 302 is arranged in a wide area. The insulation portion 310 may be filled with an insulator, such as silicon oxide, silicon nitride, and silicon oxynitride.

With such a configuration, a recess due to scratch or dishing does not tend to be formed when the CMP is performed on a pattern of the FD shielding conductive line 302 as illustrated in FIG. 5. This can thus suppress a decrease in yield due to a short circuit that occurs among wiring in a wiring layer above the FD shielding conductive line 302 can be reduced while reducing an influence on the FD conductive line 301 due to potential fluctuation.

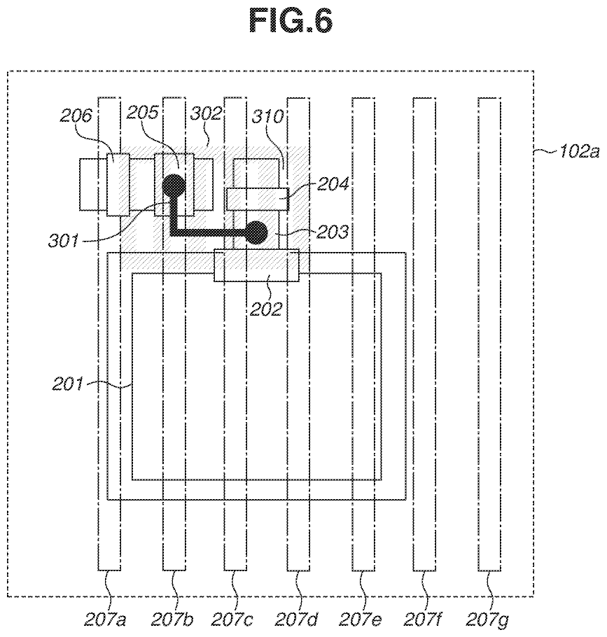

A second exemplary embodiment is described with reference to FIG. 6. The present exemplary embodiment differs from the first exemplary embodiment in a pattern of a FD shielding conductive line 302.

In the first exemplary embodiment, a pattern of the FD shielding conductive line 302 is arranged in a direction perpendicular to a direction in which the output line 207 is formed in a plan view. In the present exemplary embodiment, in contrast, a pattern of an FD shielding conductive line 302 is formed in a direction parallel to a direction in which an output line 207 is formed in a plan view. Herein, the term “perpendicular” or “parallel” includes not only a precisely perpendicular or parallel state, but also a substantially perpendicular or parallel state within a certain range of tolerance.

Even if a recess is formed by scratch or dishing, yield is less affected as long as a short circuit does not occur among the output lines 207. In the present exemplary embodiment, a pattern of the FD shielding conductive line 302 is formed in a direction parallel to upper layer wring such as the output line 207. Such a configuration can reduce a decrease in yield due to a short circuit that occurs among wiring in a wiring layer above the FD shielding conductive line 302 even if a recess caused by scratch or dishing is formed.

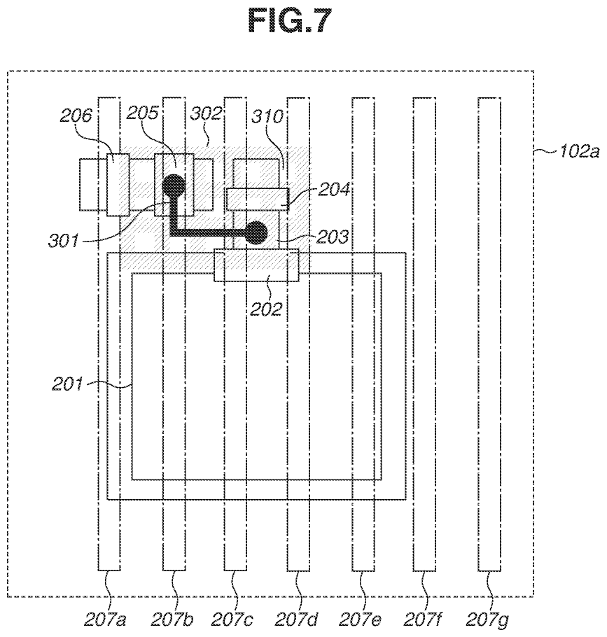

A third exemplary embodiment is described with reference to FIG. 7. In the present exemplary embodiment, a pattern of a FD shielding conductive line 302 is different from those of the first and second exemplary embodiments.

In the first and second exemplary embodiments, the patterns of the FD shielding conductive line 302 are respectively arranged in directions parallel and perpendicular to the output lines 207. In the present exemplary embodiment, in contrast, a pattern of a FD shielding conductive line 302 is formed in a lattice manner. The arrangement of the FD shielding conductive line 302 in a lattice manner can reduce a decrease in yield due to a short circuit that is caused by scratch or dishing and occurs in a wiring layer above the FD shielding conductive line 302.

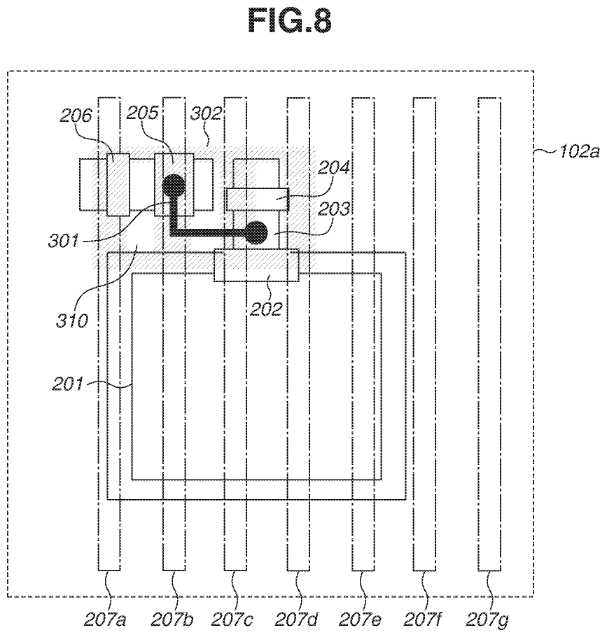

A fourth exemplary embodiment is described with reference to FIG. 8. The present exemplary embodiment differs from the first through third exemplary embodiments in a pattern of a FD shielding conductive line 302.

In the present exemplary embodiment, the pattern of the FD shielding conductive line 302 is set such that more insulation portions are arranged in an area among wiring such as output lines 207 on an upper layer. In other words, in a plan view, an area of an insulation portion not overlapping the output lines 207 is larger than an area of an insulation portion overlapping the output lines 207.

With such a configuration, a recess due to scratch or dishing does not tend to be formed in a position that can be a cause of a short circuit in upper wiring layers. Thus, a decrease in yield due to the short circuit which occurs among wiring in a wiring layer above the FD shielding conductive line 302 can be more efficiently reduced.

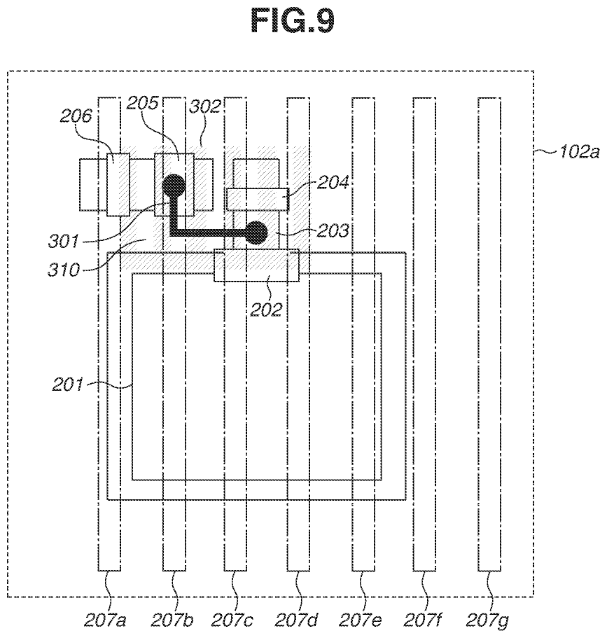

A fifth exemplary embodiment is described with reference to FIG. 9. The present exemplary embodiment differs from the first through fourth exemplary embodiments in a pattern of a FD shielding conductive line 302.

In each of the first through fourth exemplary embodiments, the FD shielding conductive line 302 is formed in a shape enclosed by an outer edge. In the present exemplary embodiment, in contrast, a FD shielding conductive line 302 is formed in a shape in which one portion of the shape is opened. Such a shape can form a finer pattern in comparison with a pattern formed in the shape enclosed by the outer edge. Even in the shape according to the present exemplary embodiment, a decrease in yield due to a short circuit that occurs among wiring in a wiring layer above the FD shielding conductive line 302 can be reduced.

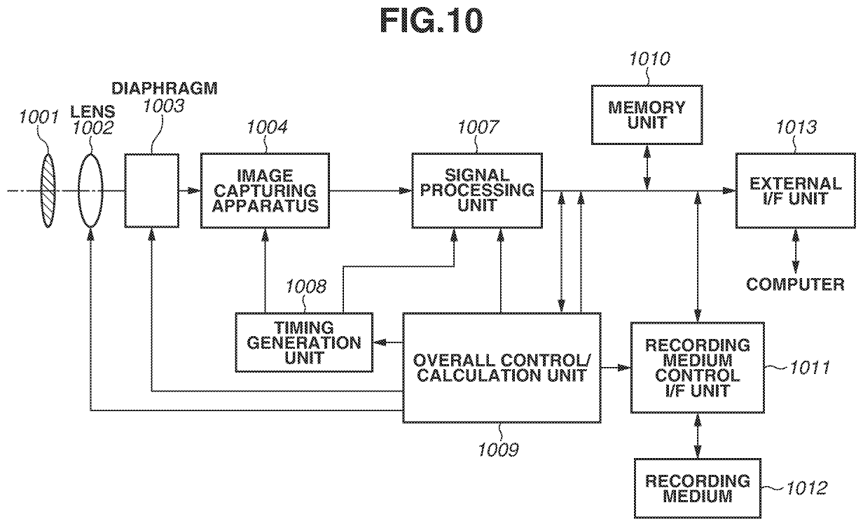

A photoelectric conversion system according to a sixth exemplary embodiment is described with reference to FIG. 10, which is a block diagram schematically illustrating a configuration of the photoelectric conversion system according to the present exemplary embodiment.

The photoelectric conversion apparatus (image capturing apparatus) described above in each of the first through fifth exemplary embodiments is applicable to various photoelectric conversion systems. Examples of the applicable photoelectric conversion systems include digital still cameras, digital camcorders, surveillance cameras, copiers, facsimile machines, mobile phones, on-board cameras, and observation satellites. Camera modules having an image capturing apparatus and an optical system such as a lens are also included as an example of the photoelectric conversion system. FIG. 10 is a block diagram illustrating an example of a digital still camera as an example of the photoelectric conversion systems.

The photoelectric conversion system illustrated in FIG. 10 includes an image capturing apparatus 1004 that is one example of the photoelectric conversion apparatus. The photoelectric conversion system illustrated in FIG. 10 also includes a lens 1002, a diaphragm 1003, and a barrier 1001. The lens 1002 forms an optical image of an object on the image capturing apparatus 1004. The diaphragm 1003 changes an amount of light that passes the lens 1002. The barrier 1001 protects the lens 1002. The lens 1002 and the diaphragm 1003 are optical systems for focusing light on the image capturing apparatus 1004. The image capturing apparatus 1004 may include one or more processors, circuitry, or combinations thereof and is the photoelectric conversion apparatus (the image capturing apparatus) according to any of the above-described exemplary embodiments, and converts the optical image formed by the lens 1002 into an electric signal.

The photoelectric conversion system also includes a signal processing unit 1007 that is an image generation unit for generating an image by processing an output signal output by the image capturing apparatus 1004. The signal processing unit 1007 may include one or more processors, circuitry, or combinations thereof, and performs various processing, such as image correction and compression, as needed to output image data. The signal processing unit 1007 can be formed on a semiconductor substrate on which the image capturing apparatus 1004 is disposed, or on a semiconductor substrate different from that on which the image capturing apparatus 1004 is disposed. Alternatively, the image capturing apparatus 1004 and the signal processing unit 1007 can be formed on a same semiconductor substrate.

The photoelectric conversion system further incudes a memory unit 1010 and an external interface (I/F) unit 1013. The memory unit 1010 temporarily stores image data, and the external I/F unit 1013 communicates with, for example, an external computer. The photoelectric conversion system also includes a recording medium 1012, such as a semiconductor memory, in which image data is recorded or to which image data is read out, and a recoding medium control I/F unit 1011 that is provided so that the image data is recorded in or read out to the recording medium 1012. The recording medium 1012 can be mounted inside the photoelectric conversion system or attachable/detachable to/from the photoelectric conversion system.

The photoelectric conversion system yet further includes an overall control/calculation unit 1009 and a timing generation unit 1008. The overall control/calculation unit 1009 controls a digital still camera in a comprehensive manner and various calculation. The timing generation unit 1008 outputs various timing signals to the image capturing apparatus 1004 and the signal processing unit 1007. Herein, a timing signal can be input from an external unit, and the photoelectric conversion system can at least include the image capturing apparatus 1004 and the signal processing unit 1007 for processing an output signal which is output from the image capturing apparatus 1004.

The image capturing apparatus 1004 outputs an imaging signal to the signal processing unit 1007. The signal processing unit 1007 performs predetermined signal processing on the imaging signal to be output from the image capturing apparatus 1004, and outputs image data. The signal processing unit 1007 uses the imaging signal to generate an image.

According to the present exemplary embodiment, therefore, the photoelectric conversion system to which the photoelectric conversion apparatus (image capturing apparatus) of any of the above-described exemplary embodiments is applied can be provided.

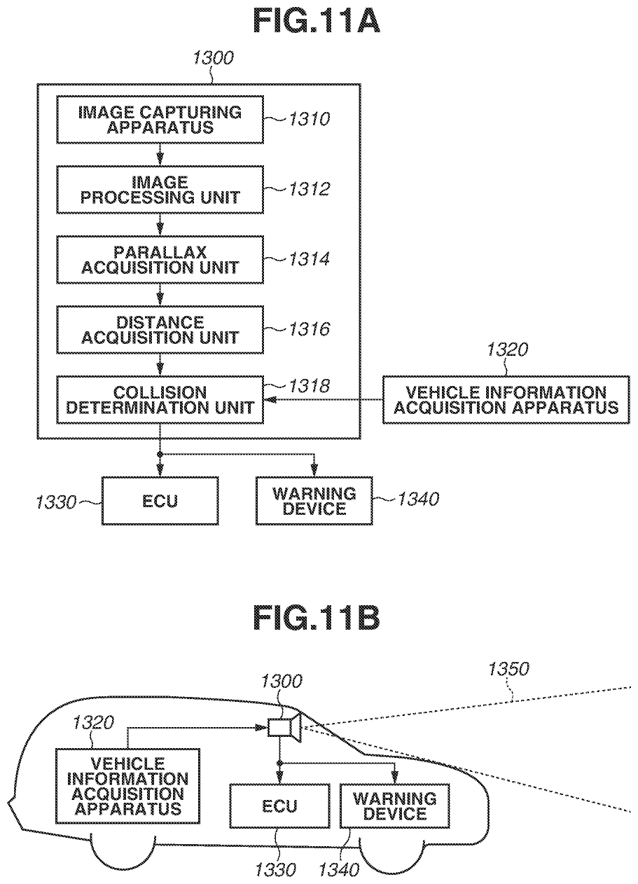

A photoelectric conversion system 1300 and a moving body according to a seventh exemplary embodiment are described with reference to FIGS. 11A and 11B. FIGS. 11A and 11B are diagrams illustrating configurations of the photoelectric conversion system 1300 and the moving body according to the present exemplary embodiment.

FIG. 11A illustrates one example of the photoelectric conversion system 1300 relating to an on-board camera. The photoelectric conversion system 1300 includes an image capturing apparatus 1310 and may include one or more processors, circuitry, or combinations thereof. The image capturing apparatus 1310 is the photoelectric conversion apparatus (image capturing apparatus) described in any of the above exemplary embodiments.

The photoelectric conversion system 1300 includes an image processing unit 1312 and a parallax acquisition unit 1314. The image processing unit 1312 performs image processing on a plurality of pieces of image data acquired by the image capturing apparatus 1310, and the parallax acquisition unit 1314 calculates a parallax (phase difference between parallax images) from the plurality of pieces of image data.

The photoelectric conversion system 1300 also includes a distance acquisition unit 1316 and a collision determination unit 1318. The distance acquisition unit 1316 calculates a distance to a target object based on the calculated parallax, and the collision determination unit 1318 determines whether there is a collision possibility based on the calculated distance.

Herein, the parallax acquisition unit 1314 and the distance acquisition unit 1316 are examples of a distance information acquisition unit for acquiring distance information about a distance to a target object. That is, the distance information includes pieces of information about a parallax, a defocus amount, and a distance to a target object. The collision determination unit 1318 can use any of those pieces of distance information to determine a collision possibility.

The distance information acquisition unit can be implemented by using dedicated hardware or a software module. Alternatively, the distance information acquisition unit can be implemented by using a circuit, such as a field programmable gate array (FPGA) and an application specific integrated circuit (ASIC), or a combination of these circuits.

The photoelectric conversion system 1300 is connected to a vehicle information acquisition apparatus 1320, so that vehicle information, such as a vehicle speed, a yaw rate, and a steering angle, can be acquired. The photoelectric conversion system 1300 is also connected to an electronic control unit (ECU) 1330 that is a control apparatus for outputting a control signal for generating a braking force to a vehicle based on a determination result of the collision determination unit 1318.

The photoelectric conversion system 1300 is also connected to a warning device 1340 for warning a driver based on a result determined by the collision determination unit 1318. For example, if the collision determination unit 1318 determines that a collision possibility is high as a determination result, the ECU 1330 controls the vehicle by applying a brake, releasing an accelerator, or controlling an engine output to avoid a collision or reduce damage. The warning device 1340 warns a user by issuing a warning such as sound, displaying warning information on a screen of a car navigation system, or vibrating a seat belt or steering wheel.

In the present exemplary embodiment, the photoelectric conversion system 1300 captures one or more surrounding images of the vehicle, such as the front or rear image of the vehicle. FIG. 11B illustrates the photoelectric conversion system 1300 in a case where an image of the front of the vehicle (an image capturing range 1350) is captured. The vehicle information acquisition apparatus 1320 issues an instruction to the photoelectric conversion system 1300 or the image capturing apparatus 1310. With such a configuration, distance measurement accuracy can be enhanced.

The present exemplary embodiment has been described using an example in which control is performed such that a vehicle does not collide with another vehicle. However, the present exemplary embodiment can be applied to a case where autonomous driving control is performed by which a vehicle follows another vehicle is performed, or a case where autonomous driving control by which a vehicle stays in a traffic lane. The photoelectric conversion system can be applied not only to a vehicle, but also to a moving body (moving apparatus), e.g., a ship, an aircraft, and an industrial robot. In addition, the application is not only limited to the moving body, but to equipment, such as an intelligent transportation system (ITS), that widely uses object recognition.

The present disclosure is not limited to the exemplary embodiments described above, but various modifications are possible. For example, the exemplary embodiments of the present disclosure include an example case in which a configuration of any of the exemplary embodiments is added to another exemplary embodiment, and an example case in which one portion of a configuration of any of the exemplary embodiments is replaced with one portion of a configuration of another exemplary embodiment.

The photoelectric conversion system according to each of the sixth and seventh exemplary embodiments described above is an example of a photoelectric conversion system to which a photoelectric conversion apparatus is applicable. A configuration of the photoelectric conversion system to which the photoelectric conversion apparatus of the present disclosure is applicable is not limited to that illustrated in each of FIGS. 10, 11A, and 11B.

The exemplary embodiments described above are merely examples of embodiments for carrying out the present disclosure, and the technical scope of the present disclosure should not be interpreted in a limited manner by these embodiments. That is, the present disclosure can be implemented in various forms without departing from the technical concept or main features thereof.

Each of the above-described exemplary embodiments can be appropriately modified within the scope of the technical concept. The disclosure of the present specification includes not only matters described in the specification, but also all of matters that can be ascertained from the specification and the attached drawings.

The disclosure of the present specification includes a complement of the concept described in the specification. That is, for example, as long as the present specification mentions that “A is bigger than B”, it is conceivable that the specification discloses that “A is not bigger than B” even if the statement “A is not bigger than B” is omitted. Because in a case in which “A is bigger than B” is mentioned, the specification is provided based on the premise that a case in which “A is not bigger than B” is considered.

According to at least one of the exemplary embodiments of the present disclosure, a technique can be provided for reducing a decrease in yield when a photoelectric conversion apparatus is manufactured while reducing an influence of potential fluctuation on an FD from wiring.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-087970, filed May 29, 2023, which is hereby incorporated by reference herein in its entirety.

What is claimed is:

1. A photoelectric conversion apparatus comprising:
a photoelectric conversion unit configured to generate a signal electric charge based on incident light;
a transfer transistor configured to transfer the signal electric charge generated by the photoelectric conversion unit to a floating diffusion;
an amplification transistor including a gate to which a signal based on a potential of the floating diffusion is input;
a wiring structure body including at least a first wiring layer, a second wiring layer which is an upper layer of the first wiring layer, and a third wiring layer which is an upper layer of the second wiring layer;
a first conductive line arranged in the first wiring layer and configured to connect the floating diffusion to the gate;
a shielding portion made of metal and arranged in the second wiring layer such that at least one portion of the shielding portion overlaps the first conductive line in a plan view; and
a second conductive line arranged in the third wiring layer such that at least one portion of the second conductive line overlaps the first conductive line in the plan view,
wherein, the shielding portion includes a plurality of insulation portions in the plan view.

2. The photoelectric conversion apparatus according to claim 1, wherein the shielding portion has a pattern that is arranged in a direction perpendicular to a direction of the second conductive line extending in the plan view.

3. The photoelectric conversion apparatus according to claim 1, wherein the shielding portion has a pattern that is arranged in a direction parallel to a direction of the second conductive line extending in the plan view.

4. The photoelectric conversion apparatus according to claim 1, wherein the shielding portion has a pattern that is arranged in directions perpendicular to and parallel to a direction of the second conductive line extending in the plan view.

5. The photoelectric conversion apparatus according to claim 1, wherein the shielding portion has a shape in which one portion of the shape is opened in the plan view.

6. The photoelectric conversion apparatus according to claim 1, wherein the plurality of insulation portions has an area that does not overlap the second conductive line that is larger than an area that overlaps the second conductive line in the plan view.

7. The photoelectric conversion apparatus according to claim 1, wherein the second conductive line is an output line connected to the amplification transistor.

8. The photoelectric conversion apparatus according to claim 1, wherein the second conductive line is a control line configured to control at least any of a plurality of transistors disposed in the photoelectric conversion apparatus.

9. The photoelectric conversion apparatus according to claim 1, wherein the shielding portion is electrically connected to a source of the amplification transistor.

10. The photoelectric conversion apparatus according to claim 1, wherein the plurality of insulation portions contains at least any of silicon oxide, silicon nitride, and silicon oxynitride.

11. A photoelectric conversion system comprising:
the photoelectric conversion apparatus according to claim 1; and
a signal processing unit configured to generate an image by using a signal output by the photoelectric conversion apparatus.

12. A moving body comprising:
the photoelectric conversion apparatus according to claim 1; and
a control unit configured to control movement of the moving body by using a signal output by the photoelectric conversion apparatus.
